(19) United States
(12) Patent Application Publication
(10) Pub. No.: US 2008/0274581 A1
(43) Pub. Date: Nov. 6, 2008

(54) METHOD FOR MANUFACTURING IMAGE SENSOR

(76) Inventor: Jin-Ho Park, Yeongju-si (KR)

Correspondence Address: SHERR & VAUGHN, PLLC, 620 HERNDON PARKWAY, SUITE 200, HERNDON, VA, 20170, US

(21) Appl. No.: 12/113,963

(22) Filed: May 2, 2008

(30) Foreign Application Priority Data
May 3, 2007 (KR) 10-2007-0042907

(51) Int. Cl. H01L 31/18; B05D 5/06

(52) U.S. Cl. 438/70; 427/58; 257/E31.127

(57) ABSTRACT

A method for manufacturing an image sensor that includes reducing the surface energy of the microlenses to prevent particles generated during a wafer sawing process from damaging the microlens or adhering to the microlens to cause a defective image.

The present application claims priority under 35 U.S.C. §119 to Korean Patent Application No. 10-2007-00472907 (filed May 3, 2007), which is hereby incorporated by reference in its entirety.

### BACKGROUND

An image sensor is a semiconductor device for converting an optical image into an electrical signal. The image sensor may be classified into a charge coupled device (CCD) and a complementary metal oxide semiconductor (CMOS) image sensor (CIS).

A CMOS image sensor may include photodiodes and MOS transistors in a unit pixel, and may function to sequentially detect electrical signals of respective unit pixels in a switching manner to realize an image.

In order to enhance light sensitivity, an image sensor may utilize technology of increasing a fill factor, which is a ratio of the area of a photodiode to the entire area of the image sensor, or technology of changing a path of light incident to a region outside the photodiode to condense the light on the photodiode.

A representative example of the condensing technology may include forming a microlens. In the process of manufacturing an image sensor, formation of the microlens may include performing a micro photo process using a special photoresist for the microlens and then performing a reflow process.

However, when a wafer is sawed after the microlens is formed, particles of the wafer may adhere to the microlens, thereby resulting in a defect. The particles generated during a sawing process considerably reduce yield, and are an important limitation. In situations where the microlens is composed of an organic material, particles generated during sawing of the wafer during a subsequent process (i.e., a bump in a package process or a semiconductor chip mounting process) may damage or adhere to the microlenses to cause a defective image.

### SUMMARY

Embodiments relate to a method for manufacturing an image sensor that can prevent particles adhering to the surface of the microlens during wafer sawing.

Embodiments relate to a method for manufacturing an image sensor that can include at least one of the following steps: forming an interlayer dielectric on a substrate including a photodiode; and then forming a color filter layer on the interlayer dielectric; and then forming microlenses on the color filter layer; and then reducing the surface energy of the microlenses.

Embodiments relate to a method for manufacturing an image sensor that can include at least one of the following steps: forming an interlayer dielectric layer on a semiconductor substrate including a plurality of photodiodes; and then forming a color filter layer on the interlayer dielectric layer; and then forming a plurality of photoresist patterns on the color filter layer by coating a photoresist on the color filter layer and selectively patterning the photoresist; and then forming a microlens array on the color filter layer by performing a first heat treatment process on the photoresist patterns; and then increasing the hydrophobicity of the microlens array; and then performing a second heat treatment process on the microlens array.

Embodiments relate to a method for manufacturing an image sensor that can include at least one of the following steps: forming an interlayer dielectric layer on a semiconductor substrate including a plurality of photodiodes; and then forming a color filter layer on the interlayer dielectric layer; and then forming a plurality of microlenses on the color filter layer; and then performing a first hexamethyldisilazane solution process on the microlenses; and then performing a heat treatment process on the microlenses.

### DRAWINGS

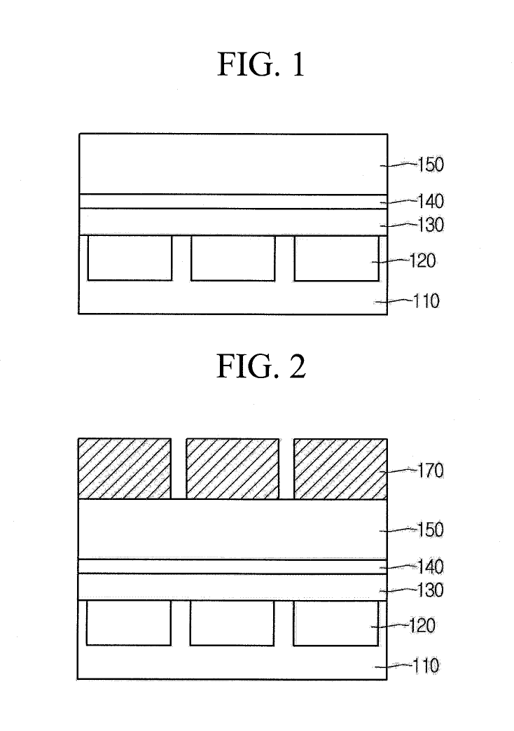

Example FIGS. 1 to 4 illustrate a process of manufacturing an image sensor, in accordance with embodiments.

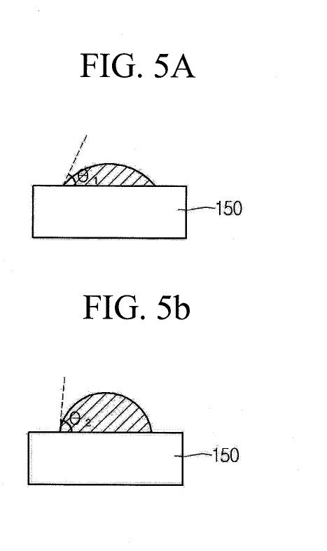

Example FIGS. 5A and 5B illustrate an effect of the method for manufacturing an image, in accordance with embodiments.

### DESCRIPTION

In the following description, it will be understood that when a layer (or film) is referred to as being ‘on’ another layer or substrate, it can be directly on the another layer or substrate, or intervening layers may also be present. Further, it will be understood that when a layer is referred to as being ‘under’ another layer, it can be directly under the another layer, and one or more intervening layers may also be present. In addition, it will also be understood that when a layer is referred to as being ‘between’ two layers, it can be the only layer between the two layers, or one or more intervening layers may also be present.

As illustrated in example FIG. 1, a method for manufacturing an image sensor in accordance with embodiments can include forming interlayer dielectric 130 on and/or over substrate 110 including photodiodes 120. A passivation layer for protecting against moisture and scratching can then be formed on and/or over interlayer dielectric 130.

Interlayer dielectric 130 can be formed as a plurality of layers. Alternatively, a first interlayer dielectric can be formed, a light blocking layer for blocking light incident to regions outside photodiode regions can then be formed on and/or over the first interlayer dielectric layer and then a second interlayer dielectric can be formed on and/or over the light blocking layer.

Color filter layer 140 can then be formed on and/or over interlayer dielectric 130. Color filter layer 140 can be formed by coating a dyeable resist on interlayer dielectric 130 and then performing an exposure and a developing process thus forming color filter layer 140 including red (R), green (G), and blue (B) filters filtering light in each wavelength band. Planarization layer (PL) 150 can then be formed on and/or over color filter layer 140 to secure flatness for controlling a focal length and forming a subsequent lens layer.

As illustrated in example FIG. 2, a plurality of photoresist patterns 170 spaced apart a predetermined interval can then be formed on planarization layer 140. Alternatively, photoresist patterns 170 can be formed directly on and/or over color filter layer 140. Photoresist patterns 170 can be formed by coating a photoresist on one of planarization layer 140 or color filter layer 130 and selectively patterning the photoresist through exposure and developing processes using microlens masks.

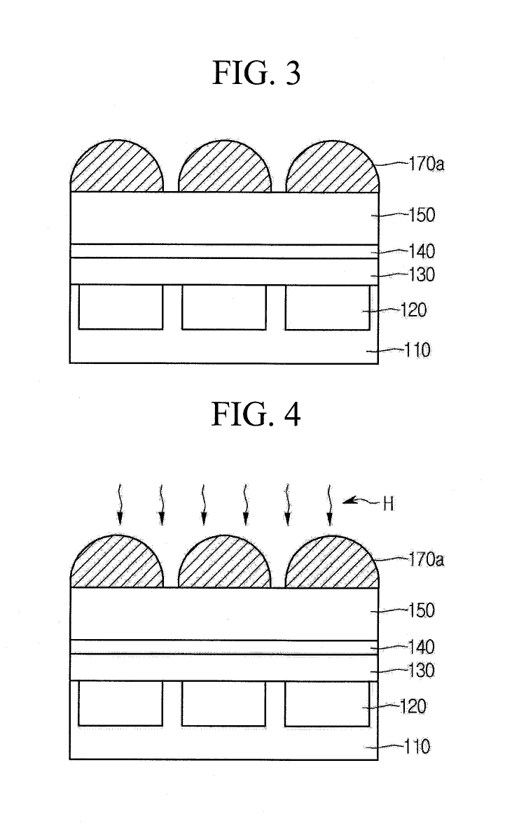

As illustrated in example FIG. 3, a microlens array including a plurality of microlenses 170a can then be formed. Microlenses 170a can be formed by placing semiconductor substrate 110 including photoresist patterns 170 and then performing a heat treatment at 150° C. or more to reflow photoresist patterns 170.

As illustrated in example FIG. 4, a process of lowering the surface energy of microlenses 170a can then be performed. The process of lowering the surface energy of each microlens 170a can include processing each microlens 170a using a hexamethyldisilazane solution (H). For example, a hexamethyldisilazane solution can be evaporated and sprayed on and/or over microlenses 170a. Particularly, the hexamethyldisilazane solution can be changed into a hexamethyldisilazane gas generating forced bubbling using a nitrogen gas. The hexamethyldisilazane gas can then be sprayed on and/or over each microlens 170a.

As illustrated in example FIG. 5A, prior to lowering the surface energy of each microlens 170a using the hexamethyldisilazane solution, each microlens 170a has first contact angle θ₁. A hydroxide ion (OH⁻) group adheres to each microlens 170a so that first contact angle θ₁ relatively changes to have hydrophilicity.

As illustrated in example FIG. 5B, each microlens 170 has second angle θ₂ after processing using the hexamethyldisilazane solution (H). Reaction equation 1 is a reaction process between each microlens 170a and the hexamethyldisilazane solution.

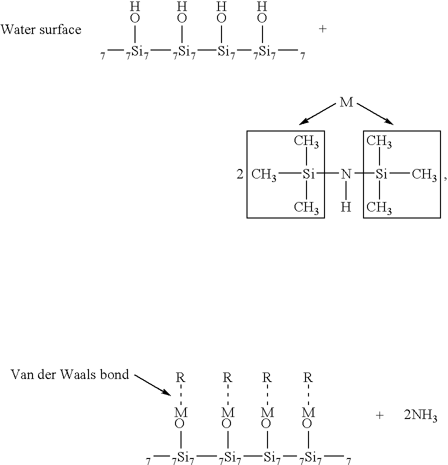

After processing each microlens 170a using the hexamethyldisilazane solution (H), the hexamethyldisilazane solution combines with a hydroxide ion (OH⁻) to have hydrophobicity while generating NH₃ gas.

The hexamethyldisilazane solution process (H) can be performed at a temperature range of about 90-150° C. in accordance with embodiments in order to further increase the hydrophobicity of each microlens 170a. For example, the hexamethyldisilazane solution process (H) can be performed at a temperature of about 140° C. to even further increase hydrophobicity but is not limited to such a temperature.

The method for manufacturing the image sensor in accordance with embodiments can further include performing heat treatment on microlenses 170a after reducing the surface energy of microlenses 170a.

The surface of microlens 170a has hydrophobicity through the reaction process between microlens 170a and the hexamethyldisilazane solution as illustrated by Reaction equation 1. The bond between microlens 170a and the hexamethyldisilazane solution, however, is a Van der Waals bond, and thus, microlens 170a may have hydrophilicity again as time elapses. That is, although the surface of microlens 170a has hydrophobicity through the reaction process between microlens 170a and the hexamethyldisilazane solution, a hydroxide ion (OH⁻) group in the atmosphere may adhere to the surface of microlens 170a, thereby microlens 170a may again have hydrophilicity. Accordingly, the effect of hydrophobicity may disappear as time elapses because microlens 170a and the hexamethyldisilazane solution are bonded to each other through a Van der Waals bond.

Performing a second heat treatment process for a predetermined time after reducing the surface energy of microlenses 170a can further increase contact angle θ₂ to reduce the surface energy. For example, the second heat treatment on microlens 170a can be performed after about one hundred hours to one hundred fifty hours of reducing the surface energy of microlens 170a.

The second heat treatment on microlens 170a can be performed at about 90-150° C. for about 30-90 seconds. For example, the performing of the second heat treatment on microlens 170a can be performed at a temperature of 110° C. for about 60 seconds to increase the contact angle θ₂ of microlens 170a, thereby further reducing the surface energy of microlens 170a. Therefore, adhering of the particles to microlens 170a can be prevented and yield can be remarkably increased.

The method for manufacturing an image sensor in accordance with embodiments reduces the surface energy of the microlens to prevent particles generated during a wafer sawing process from damaging the microlens or adhering to the microlens to cause a defective image.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method for manufacturing an image sensor, the method comprising:
forming an interlayer dielectric on a substrate including a photodiode; and then
forming a color filter layer on the interlayer dielectric; and then
forming microlenses on the color filter layer; and then
reducing the surface energy of the microlenses.

2. The method of claim 1, wherein reducing the surface energy of the microlenses comprises applying a hexamethyldisilazane solution on the microlenses.

3. The method of claim 1, wherein reducing the surface energy of the microlens comprises changing the hydrophilicity of the microlenses into hydrophobicity.

4. The method of claim 1, further comprising, after reducing the surface energy of the microlenses, performing a heat treatment process on the microlenses.

5. The method of claim 4, wherein the heat treatment process is performed on the microlens after about 100-150 hours after applying the hexamethyldisilazane solution.

6. The method of claim 4, wherein the heat treatment process is performed at a temperature range of about 90-150° C.

7. The method of claim 4, wherein the heat treatment process is performed for about 30-90 seconds.

8. The method of claim 2, wherein the hexamethyldisilazane solution is applied at a temperature range of about 90-150° C.

9. A method comprising:
forming an interlayer dielectric layer on a semiconductor substrate including a plurality of photodiodes; and then
forming a color filter layer on the interlayer dielectric layer; and then
forming a plurality of photoresist patterns on the color filter layer by coating a photoresist on the color filter layer and selectively patterning the photoresist; and then
forming a microlens array on the color filter layer by performing a first heat treatment process on the photoresist patterns; and then
increasing the hydrophobicity of the microlens array; and then
performing a second heat treatment process on the microlens array.

10. The method of claim 9, wherein the first heat treatment process is performed at a temperature of 150° C. or more.

11. The method of claim 9, wherein the second heat treatment is performed on the microlens array after about 100-150 hours of increasing the hydrophobicity of the microlens array.

12. The method of claim 9, wherein increasing the hydrophobicity of the microlens array comprises applying a hexamethyldisilazane solution to the microlens array.

13. The method of claim 12, wherein the hexamethyldisilazane solution is applied at a temperature range of about 90-150° C.

14. The method of claim 12, wherein the hexamethyldisilazane solution is applied at a temperature of about 140° C.

15. The method of claim 9, wherein the second heat treatment process is performed at a temperature of about 90-150° C. for about 30-90 seconds.

16. The method of claim 9, wherein the second heat treatment process is performed at a temperature of 110° C. for about 60 seconds.

17. A method comprising:
forming an interlayer dielectric layer on a semiconductor substrate including a plurality of photodiodes; and then
forming a color filter layer on the interlayer dielectric layer; and then
forming a plurality of microlenses on the color filter layer; and then
performing a first hexamethyldisilazane solution process on the microlenses; and then
performing a heat treatment process on the microlenses.

18. The method of claim 17, wherein the heat treatment process is performed after about 100-150 hours of performing the hexamethyldisilazane solution process.

19. The method of claim 17, wherein the hexamethyldisilazane solution process is performed at a temperature of about 140° C.

20. The method of claim 17, wherein the heat treatment process is performed at a temperature of 110° C. for about 60 seconds.
